(19) United States
(12) Patent Application Publication
(10) Pub. No.: US 2012/0242364 A1
(43) Pub. Date: Sep. 27, 2012

(54) FLEXIBLE CONNECTING CABLE FOR ELECTRICALLY CONNECTING A TRANSDUCER AND A TRANSMITTER OF A MEASUREMENT MODULE

(75) Inventor: Gerd Ohmayer, Haslach (DE)

(73) Assignee: VEGA Grieshaber KG, Wolfach (DE)

(21) Appl. No.: 13/325,889

(22) Filed: Dec. 14, 2011

Related U.S. Application Data
(60) Provisional application No. 61/469,583, filed on Mar. 30, 2011.

(30) Foreign Application Priority Data
Mar. 25, 2011 (EP) 11 002495.7

(51) Int. Cl. G01R 31/00

(52) U.S. Cl. 324/756.05

(57) ABSTRACT

The invention relates to a connection cable for an electric connection of a measuring sensor and an evaluation electronics package of a measuring module. More specifically, the present invention relates to a module for fill level measuring technology, with the connection cable being designed as a flexible circuit board with at least one conductor path. The invention moreover relates to a measuring module with a connection cable according and having a housing to accommodate a measuring sensor and an evaluation electronics circuit. According to the invention, it is provided that the circuit board is designed with first and second circuit board end sections and a number of 2n+1 (n≧1) circuit board sections of essentially the same length lying in between, the circuit board end sections being designed as connection points projecting above bending sections opposite in the direction of the circuit board sections.

### CROSS REFERENCE TO RELATED APPLICATIONS

This application relates to and claims priority from European App. Ser. No. 11 002 495.7 filed Mar. 25, 2011, the entire contents of which are incorporated herein by reference; this application also claims priority from U.S. Prov. Ser. No. 61/469,583 filed Mar. 30, 2011, the entire contents of which are incorporated herein by reference.

### FIGURE SELECTED FOR PUBLICATION

FIG. 4

### BACKGROUND OF THE INVENTION

1. Field of the Invention

The invention relates to a connection cable for an electric connection of a measuring sensor and an evaluation electronics package of a measuring module. More specifically, the present invention relates to a module for fill level measuring technology, with the connection cable being designed as a flexible circuit board with at least one conductor path. The invention moreover relates to a measuring module with a connection cable according and having a housing to accommodate a measuring sensor and an evaluation electronics circuit.

2. Description of the Related Art

The related art involves teachings such as that found in DE 198 19 088 A1, wherein a flexible circuit board made of a carrier foil supporting a multitude of conductor paths is disclosed. This conductor path structure is used as cable harness, for an electric contact of a certain arrangement of electric and electronic components. With regard to its spatial extension relative to the ready-to-install harness-like circuit board, the conductor path layout of the circuit board is produced in a compressed production assembly in which bending points are provided in predetermined sections at which the adjoining conductor path branches can be bent from their production arrangement to their intended mounted arrangement. In this manner, with the aid of an arrangement of a meandering conductor path branch connected with such bending points, a long conductor path branch can be realized by bending it.

What is not appreciated by the prior art is that only one particular use will be possible since the layout of this circuit board is adapted thereto.

Additionally, in the case of measuring modules in the field of fill level measuring technology, there is the disadvantage that for the measuring sensors and evaluation electronics arranged in a cylindrical housing on opposite end walls of such a housing, different lengths of connection cables connecting a measuring sensor and an evaluation electronics will be required for different housing lengths. Therefore, different structural lengths of such measuring modules will require connection cables of different lengths.

Accordingly, there is a need for an improved connection cable of the type mentioned above that will permit a wide array of uses, in particular without the aforementioned disadvantages, suitable for use in measuring modules of different structural lengths.

### ASPECTS AND SUMMARY OF THE INVENTION

An aspect of the present invention is to provide a an improved connection cable of the type mentioned above that will permit a wide array of uses, in particular without the aforementioned disadvantages, suitable for use in measuring modules of different structural lengths.

The needs in the art are initially met by a connection cable for an electric connection of a measuring sensor and an evaluation electronics circuit of a fill level measuring module, wherein the connection cable comprises a flexible circuit board having at least one conductor path, and where at least two circuit board sections lie next to each other and are connected via at least one bending section, and, adjacent areas of the flexible circuit board are detachably connected via a bridge. Additionally, the connection cable comprises a first and a second circuit board end section, and a plurality of circuit board sections,

Such a connection cable for an electric connection of a measuring sensor and an evaluation electronics of a measuring module, in particular of a measuring module for fill level measuring technology, that is designed as a flexible circuit board with at least one conductor path and the flexible circuit board comprising at least two adjacent circuit board sections connected by at least one bending section and adjacent areas of the flexible circuit board being detachably connected at least by a bridge, distinguishes itself according the invention in that that the circuit board is designed with a first and second circuit board section and a number 2n+1 (n≧1) of circuit board sections of essentially the same length located in between; the circuit board segments are designed as connecting points protruding relative to bending sections located opposite in the direction of the circuit board sections, to with their extension transversely to the direction of the circuit board sections corresponding essentially to the width of the circuit board sections lying next to each other; the first circuit board section is connected as connecting point with the measuring sensor and the second circuit board section as connecting point with the evaluation electronics; and the circuit board end sections are detachably connected with the adjacent bending sections, in each case by at least one bridge, thereby making an extension of the connection cable possible to adjust its length to the distance between the measuring sensor and the evaluation electronics.

Different structural lengths between electric modules can be bridged with the aid of the connection cable according to the invention. In the production arrangement, the connection cable according to the invention basically corresponds to a standard length; however, should this length be insufficient, the corresponding number of circuit path sections can be unfolded by breaking the bridges at the bending sections. In this case, the extension will occur step by step with a length that in each case essentially corresponds to the length of the circuit board sections. An extended connection cable can be produced thereby from a connection cable of short standard length without any reassembly, with any desirable unfolding lengths being achievable depending on the number of circuit board sections.

Such a connection cable according to the invention is particularly suitable for use in the field of measuring technology where a measuring sensor and an evaluation electronics package of a measuring module must be connected and different structural lengths between such electric modules must be bridged, depending on the field of application.

With such a connection cable, according to the present invention, it will now no longer be necessary to manufacture different pre-modules during the manufacturing process that would differ only in their structural length.

Moreover, such a connection cable according to the invention will allow the mounting of electric and/or electronic components on the flexible circuit board, thereby creating the possibility of an automatic assembly or mounting.

The connection cable according to the invention can be produced cost-effectively in a short time in great quantities and at a high degree of automatization.

In one embodiment of the invention according to the first solution, the circuit board sections are designed as connection points essentially having a rectangular shape. Since these connection points are connected with the adjacent bending section via a bridge, the rectangular shape of the circuit board section will result in easy handling when such a bridge is to be broken to unfold a circuit board section.

During its production state, the connection cable according to the invention consists of at least three circuit board sections and, in its fully unfolded state, corresponds to almost threefold the standard length. The next unit size consists of at least five (2n+1, n≧3) circuit board sections in which, according to a further development of the invention, the circuit board end sections are in each case connected with all adjoining bending spots via detachable bridges. With that, the standard length can be extended by the length of two circuit board sections, or, if all bridges are broken, by the length of four circuit board sections.

According to a particularly advantageous further development of the invention, a large number of identical connection cables can be produced simultaneously since a majority of circuit boards are arranged parallel with regard to the circuit board sections in one carrier (PCB panel) and adjacent circuit boards are in each case detachably connected via bridges in the area of the circuit board end sections. Such connection cables according to the invention arranged in one PCB panel can be separated by breaking the bridges connecting the adjacent circuit board end sections.

This results in the advantageous possibility of mounting the connection cables in the PCB panel, and to separate them only afterwards.

It makes sense to form the PCB panel in such a way that in each case the first or, respectively, second circuit board end sections connected via a bridge in each case together form a marginal section of the carrier so as to facilitate the handling of the PCB panel.

Finally, in another design of the PCB according to the invention, the bridges connecting the circuit board end sections can in each case be arranged on the side of the edge of the marginal sections. In this way, the slits in the circuit board that separate the adjoining circuit board sections from two connection cables lying next to each other can be moved almost to the edge of the PCB panel so that no additional manufacturing steps will be required for these bridges.

In an advantageous way, it makes sense to design the PCB panel essentially with a rectangular shape so that the two marginal sections represent opposite sides of the PCB panel.

This second-mentioned solution proposes a connection cable for an electric connection of a measuring sensor and an evaluation electronics of a measuring module that is designed as a flexible circuit board with at least one conductor path that, according to the invention, is designed starting with a first circuit board end section running helically outwardly in one plane with several spiral turns and ending in a second circuit board end section; that the first circuit board section as connection point is connected with the measuring sensor and the second circuit board section as connection point with the evaluation electronics, and that bridges are provided in each case between the spiral turns that detachably connect adjacent spiral turns of the circuit board, thereby facilitating an extension of the connection cable to adapt its length to the distance between the measuring sensor and the evaluation electronics.

In the case of this connection cable according to the invention, different structural lengths can be realized as well by braking out bridges, starting from the first centrically arranged circuit board end section, so that at least one spiral turn can be folded or, respectively, bent out of the plane of the spiral structure. If all bridges connecting the individual spiral turns are broken, a conical spiral shape of the connection cable will result with a maximal length of the connection cable. Corresponding to the number of spiral turns, different heights of the conical spiral shape will result and therefore different cable lengths.

According to a further development of the invention, it will be particularly advantageous if the connection cable is designed with a bridge connecting adjacent spiral turns, in each case after a half spiral turn, so that the bridges will lie on a diameter of the spiral structure, whereby, on the one hand, a stable structure will be realized and, on the other hand, an easy unfolding of this structure will be made possible. In an advantageous manner according to an embodiment of the invention, at least one bridge will be provided in the area of the second circuit board end section. This will facilitate improved handling during the breaking of this bridge.

Finally, this objective will also be solved by a connection cable for an electric connection of a measuring sensor and an evaluation electronics of a measuring module having the characteristics of patent claim 12.

According to this solution, the connection cable designed as flexible circuit board with at least one conductor path distinguishes itself according to the invention in that two flexible circuit board sections are designed in rolled-up fashion, beginning with a bending section connecting the circuit board sections, running outwardly in spiral shape with several spiral turns bifilarly vertically to the plane of the circuit board and ending with circuit board end sections; that a first circuit board section as connection point is connected with the measuring sensor and a second circuit board as connection point with the evaluation electronics; and that an extension of the connection cable is made possible to adapt its length to the distance between the measuring sensor and the evaluation electronics by uncoiling the extension cable.

This connection cable according to the invention can be extended steplessly up to a maximal length by completely uncoiling the spiral, with any desired length being attainable by means of partial uncoiling.

In one embodiment of the invention, a differential of one half spiral turn is provided between the circuit board end sections, thereby making the handling during the uncoiling of the connection cable easier.

A particularly advantageous further development of the invention will result if a majority of flexible circuit boards are arranged parallel in one carrier (PCB panel) and adjacent circuit boards are detachably connected via bridges in the area of the spiral turns and/or in the area of the circuit board end sections. In this way, this connection cable according to the invention can also be produced simultaneously in large numbers and subsequently be separated by breaking the bridges.

Finally, it will be particularly advantageous if the circuit board end section are designed according to the further development as essentially rectangular connection points.

A simple geometrical arrangement in the PCB panel will thereby be possible and easy handling during separation and uncoiling will be assured.

A measuring module whose measuring sensor and evaluation electronics are connected via such a connection cable according to the invention distinguishes itself, in that the first circuit board section as connection point is connected with the measuring sensor and the second circuit board section as connection point with the evaluation electronics. Therefore, the connection cable according to the invention can be used in its production state.

In one embodiment of the present invention, it is provided that, either by breaking the bridges of the connection cable and unfolding it or by uncoiling the connection cable, an extension of the connection cable will be made possible in order to adapt the length of the connection cable to the distance between the measuring sensor and the evaluation electronics that are arranged in the housing.

In another embodiment of the present invention, the housing of the measuring module is designed cylindrically, with the measuring sensor and the evaluation electronics being arranged on opposite end walls of the cylindrically shaped housing.

Moreover, according to the further development, it will be advantageous if the connection cable in its unfolded or uncoiled state has a length at which the measuring sensor and the evaluation electronics can be connected with the cylindrically shaped housing via the connection cable guided through the housing.

Preferably, the measuring module will be designed for fill level measurements.

The above, and other aspects, features and advantages of the present invention will become apparent from the following description read in conjunction with the accompanying drawings, in which like reference numerals designate the same elements.

### BRIEF DESCRIPTION OF THE DRAWINGS

FIG. 1 is a connection cable in its production state as an example of an embodiment of the invention with three circuit board sections connected with each other via two bending sections.

FIG. 2 is a connection cable according to FIG. 1 in its unfolded state.

FIG. 3 is a representation of a carrier (PCB panel) with several connection cables according to the invention as per FIG. 1.

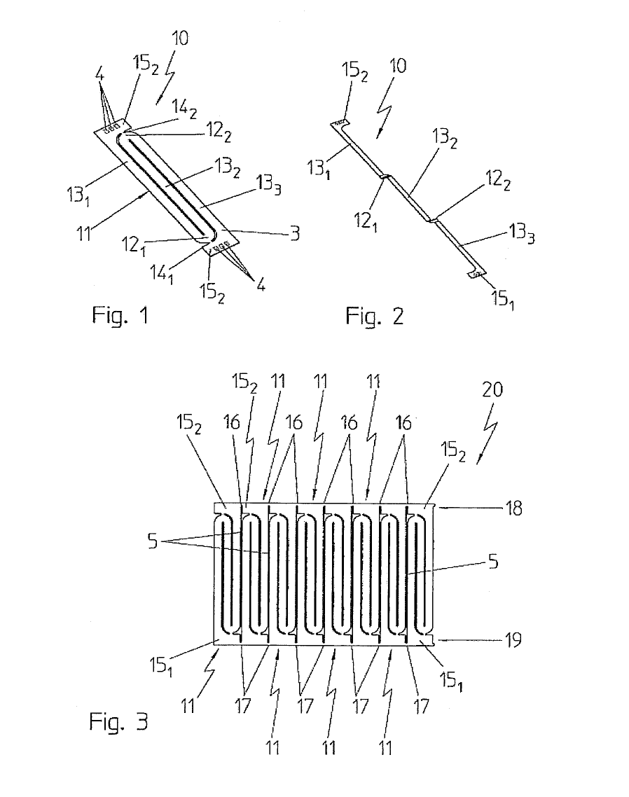

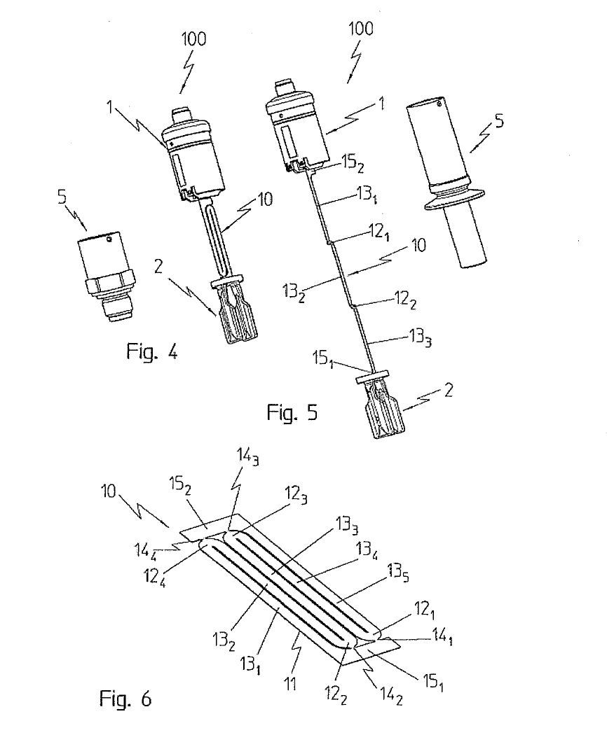

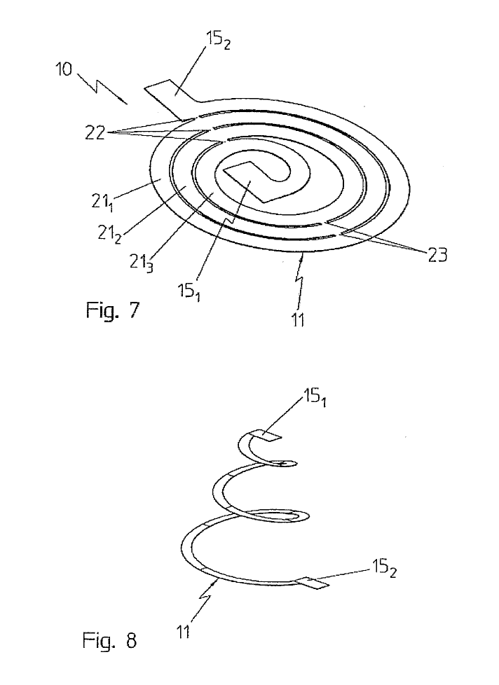

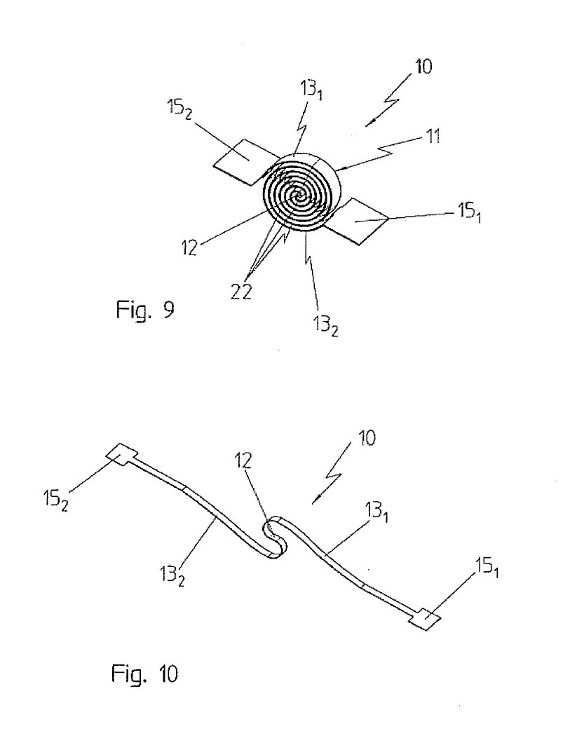

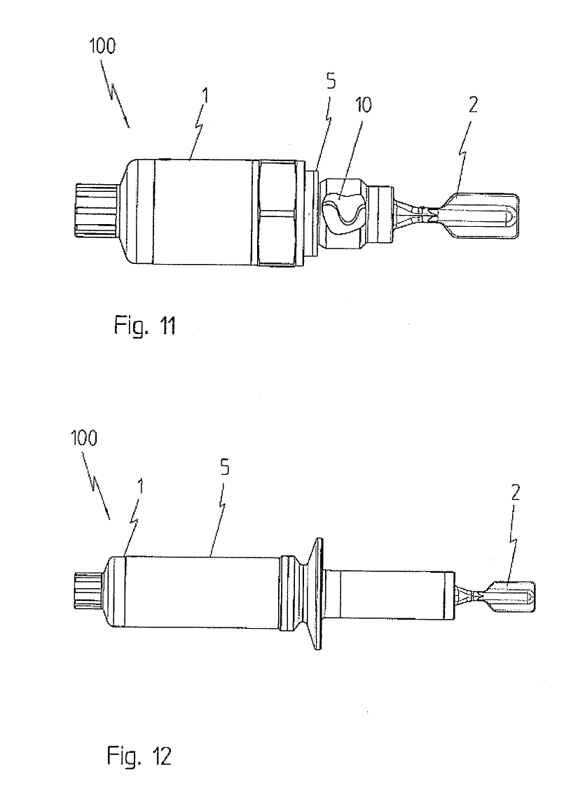

FIG. 4 is a representation of a use of a connection cable according to FIG. 1 in its standard length for a connection of a measuring sensor and an evaluation electronics of a measuring module.

FIG. 5 is a representation of a measuring module according to FIG. 4 with a greater structural length in which the connection cable has been completely unfolded to its maximal length.

FIG. 6 is a connection cable in its production state as an additional example of an embodiment of the invention with five circuit board sections.

FIG. 7 is a connection cable in its production state as an additional example of an embodiment of the invention with a spiral-shaped structure.

FIG. 8 is a representation of the connection cable according to FIG. 7 in its unfolded state.

FIG. 9 is a connection cable in its production state as an additional example of an embodiment of the invention with a spiral-shaped structure.

FIG. 10 is a representation of the connection cable according to FIG. 9 in its unfolded state.

FIG. 11 is a representation of the measuring module according to FIG. 4 in its assembled state.

FIG. 12 is a representation of the measuring module according to FIG. 5 in its assembled state.

### DETAILED DESCRIPTION OF THE PREFERRED EMBODIMENTS

Reference will now be made in detail to several embodiments of the invention that are illustrated in the accompanying drawings. Wherever possible, same or similar reference numerals are used in the drawings and the description to refer to the same or like parts or steps. The drawings are in simplified form and are not to precise scale. For purposes of convenience and clarity only, directional terms, such as top, bottom, up, down, over, above, and below may be used with respect to the drawings. These and similar directional terms should not be construed to limit the scope of the invention in any manner. The words “connect,” “couple,” and similar terms with their inflectional morphemes do not necessarily denote direct and immediate connections, but also include connections through mediate elements or devices.

The connection cable 10 according to FIG. 1 is produced as a flexible circuit board 11 and structured by means of slits in such a way that three straight-lined circuit board sections 13₁, 13₂ and 13₃ are arranged next to each other and connected via bending sections 12₁ and 12₂, with the opposite ends of the two to exterior circuit board sections 13₁ and 13₃ projecting above the bending section 12₁ or, respectively, 12₂ and transitioning there into a first circuit board end section 15₁ or, respectively, into a second circuit board end section 15₂, with these circuit board end sections 15₁ and 15₂ being designed as rectangular-shaped connection points of the connection cable 10 and extending transversely to the direction of the circuit board sections 13₁ and 13₃ across their entire width so that overall, a rectangular-shaped form will result for this circuit board 11. The circuit board end sections 15₁ and 15₂ are detachably connected with the bridge sections 12₁ and 12₂ via bridges 14₁ and 14₂.

On the circuit board 1, several conductor paths 3 ending in connection pads 4 at the connection points 15₁ and 15₂ are run between the circuit board end sections 15₁ and 15₂ along the circuit board sections 13₁, 13₂ and 13₃ and the bending sections 12₁ and 12₂. Such circuit boards 11 are produced in a familiar manner and consist of a conductive intermediate layer between two high temperature resistant insulation layers.

From FIG. 1 it can therefore be seen that the layout of the circuit board 11 with conductor paths 3 follows a meandering course. By breaking the bridges 14₁ and 14₂, the connections between the circuit board end sections 15₁ and 15₂ and the bending sections 12₁ and 12₂ are disconnected so that the circuit board 11, according to FIG. 2, can be folded up at the bending sections 12₁ and 12₂ into a connection cable 10 of maximum length.

FIG. 3 shows a PCB panel 20 that is designed as a rectangular-shaped carrier with which several circuit boards 11 are combined according to FIG. 1 that can be used as connection cables 10 after their separation. In this way, a large number of identical connection cables 10 can be produced simultaneously. For the sake of simplicity, the conductor paths are not represented on this carrier.

According to FIG. 3, the individual circuit board parts that in each case represent one circuit board 11 are arranged parallel relative to their circuit board sections 13₁ through 13₃ and are separated by slits S also running parallel to the circuit board sections except for separable bridges 16 and 17 remaining at the edge. These bridges 16 and 17 connect adjacent circuit board end sections 15₁ and 15₂ and together form, across the entire carrier 20, in each case opposite marginal sections 18 and 19 of said carrier 20.

The separation of the circuit boards 11 into connection cables 10 according to FIG. 1 occurs by breaking these bridges 16 and 17.

The connection cable 10 according to FIG. 1 can be used in its production state in which it has a standard length, and it can be used for the connection of electrical modules. FIG. 4 shows such a use in which the standard length of the connection cables 10 suffices for an electric connection of a measuring sensor 2 and an evaluation electronics 1 of a measuring module 100 designed as a fill level measuring device. To this end, the connection pads 4 of the circuit board end section 15₁ are electrically connected with the measuring sensor 2 and the connection pads 4 of the other circuit board end section 15₂ with the evaluation electronics 2. The two components of this measuring module 100, the measuring sensor 2 and the evaluation electronics 1, are accommodated in a cylinder-shaped housing 5, with these components being mounted in each case on an end wall of this housing 5, with the housing being represented separately in FIG. 4 for the sake of a better overview. FIG. 11 shows the fill level measuring device 100 in its assembled state with a short structural length.

Should this standard length of the connection cable 10 be insufficient, the circuit board sections 13₁ and 13₂ can be unfolded by breaking the bridges 14₁ and 14₂ at the bending sections 12₁ and 12₂ as shown in FIG. 2. The standard length will thereby be extended by approximately two circuit board sections. FIG. 5 shows the corresponding application according to which a measuring sensor 2 is electrically connected with this extended connection cable 10 in the same way with an evaluation electronics 1 of a measuring module 100 designed as a fill level measuring device. However, in contrast with the measuring module 100 according to FIG. 4, the appurtenant housing 5 of this measuring module according to FIG. 5 is considerably longer so that in the assembled state of this measuring module 100 according to FIG. 12 its structural length will be greater as well.

The assembly of the components of this measuring module 100 according to FIGS. 4 and 5 occurs in such a way that initially the measuring sensor 2 is electrically connected with the connection cable 10 via the connection points 4 of the circuit board end section 15₁; subsequently, the measuring sensor 2 with the connection cable 10 is mounted at one end wall of the housing 5 so that in this case the other circuit board end section 15₂ will protrude at the other end of the housing 5 in order to facilitate the electric connection of the evaluation electronics 1 with the connection points 4 of this other circuit board end section 15₂. Finally, this evaluation electronics 1 is mounted at the housing 5 so that the state according to FIGS. 11 and 12 is realized.

Thus, such a measuring sensor 2 together with the extension cable 10 can be produced as a pre-component that will then be usable for measuring modules 100 of different lengths.

FIG. 6 shows a connection cable 10 in which, for the sake of simplicity, the conductor paths are not represented but are in principle designed corresponding to the connection cable according to FIG. 1. The difference relative to the connection cable 10 according to FIG. 1 lies in the fact that the circuit board 11 does not consist of three circuit board sections but of five parallely arranged circuit board sections 13₁, 13₂, 13₃, 13₄, 13₅, and instead of in each case one bending section on opposite sides, two bending sections 12₁ and 12₂ or, respectively, 12₃ and 12₄ are in each case provided on both sides that connect corresponding circuit board sections 13₁, 13₂, 13₃, 13₄, 13₅ with each other. In this embodiment, too, the exterior circuit board sections 13₁ and 13₅ end in each case in a first and second rectangular-shaped circuit board end section 15₁ and 15₂ projecting beyond the bending sections 12₁ and 12₂ or, respectively, 12₃ and 12₄, with the end sections 15₁ and 15₂ also extending vertically to the direction of the circuit board sections 13₁, 13₂, 13₃, 13₄, 13₅ across their entire width and representing connection points of the connection cable 10. The circuit board end sections 15₁ and 15₂ are detachably connected with the bending sections 12₁ and 12₂ or, respectively, 12₃ and 12₄, in each case via bridges 14₁ and 14₂ or, respectively, 14₃ and 14₄.

This connection cable 10 according to FIG. 6, together with its connection points 15₁ and 15₂, also has a standard length for a connection of modules and can, if need be, be extended by breaking the bridges 14₁ through 14₄ by up to approximately four lengths of a circuit board section by unfolding the circuit board sections 13₁ through 13₅ at the bending points 12₁ through 12₄.

Of course it will also be possible to break, for example, only the bridges 14₁, 14₃ and 14₄ so that the circuit board end section 15₁ can be unfolded together with two circuit board sections 13₄ and 13₅ in order to be given only a threefold standard length in lieu of a fivefold one.

The connection cables 10 according to FIGS. 1 and 6 have, as examples of embodiments, a number (2n+1) of circuit board sections, with n=1 and n=3. Of course, connection cables with a greater number, i.e. with n>3, can be realized as well.

The additional example of an embodiment of a connection cable 10 is designed according to FIG. 7 in one plane as a spiral-shaped circuit board 11, with the representation of the conductor paths having been dispensed with here as well.

The spiral-shaped structure of this circuit board 11 starts with a first circuit board end section 15₁ and runs helically outwardly in one plane with several spiral turns 21₁, 21₂ and 21₃ and ends in a second circuit board end section 15₂. In to each case, bridges 22 and 23 are provided between the spiral turns 21₁, 21₂ and 21₃ that detachably connect the latter. In this context, the bridges 22 are arranged flush with the second circuit board end section 15₂ on the same side of the spiral structure while on the other side, i.e. at a differential of a half spiral turn, the other bridges 23 connect the spiral turns, with all bridges 22 and 23 lying on a diameter of the spiral structure.

By breaking the bridges 22 and 23, this two dimensional spiral structure can be unfolded into a three dimensional structure so that a conical spiral shape of the connection cable 10 having maximum length will result between the circuit board end sections 15₁ and 15₂ that are designed as connection points of the connection cable 10, as shown in FIG. 8.

It is also possible to realize a shorter cable length than the maximal length by breaking out bridges 22 and 23 starting from the first centrically arranged circuit board section 15₁ so that at least one spiral turn 21₃ can be folded or, respectively, bent from the plane of the spiral structure.

Finally, according to FIG. 9, the last example of an embodiment of a connection cable 10 likewise has a spiral structure in which case, however, the circuit board 11 does not run in the plane in the shape of a spiral but is coiled vertically to the plane of the circuit board 11 in a spiral shape running outwardly with several spiral turns 22. This connection cable 10 consists of two strip-shaped flexible circuit board sections 13₁ and 13₂ that are designed in coiled fashion, starting with a bending section 12 connecting these two circuit board sections 13₁ and 13₂ running outwardly in spiral shape bifilarly vertically relative to the plane of the circuit board 11 and ending with circuit board end sections 15₁ and 15₂, with these two rectangular circuit board end sections 15₁ and 15₂ being arranged diametrically opposite each other, i.e. with a differential of a half spiral turn 22.

As FIG. 10 shows, this connection cable 10 can be extended steplessly to a maximum length by uncoiling the spiral, with any desired shorter length being achievable by means of a partial uncoiling.

Several connection cables 10 according to FIGS. 9 and 10 can be combined as individual circuit boards 11 in one carrier (PCB panel) not shown in the figures by arranging them parallel in such a carrier and by detachably connecting adjacent circuit boards 11 in the area of the spiral turns 22 and/or in the area of the circuit board end sections 15₁ and 15₂ via bridges. Thus, the connection cables 10 can be created by separating the circuit boards 11 by breaking these bridges.

In the claims, means or step-plus-function clauses are intended to cover the structures described or suggested herein as performing the recited function and not only structural equivalents but also equivalent structures. Thus, for example, although a nail, a screw, and a bolt may not be structural equivalents in that a nail relies on friction between a wooden part and a cylindrical surface, a screw's helical surface positively engages the wooden part, and a bolt's head and nut compress opposite sides of a wooden part, in the environment of fastening wooden parts, a nail, a screw, and a bolt may be readily understood by those skilled in the art as equivalent structures.

Having described at least one of the preferred embodiments of the present invention with reference to the accompanying drawings, it is to be understood that the invention is not limited to those precise embodiments, and that various changes, modifications, and adaptations may be effected therein by one skilled in the art without departing from the scope or spirit of the invention as defined in the appended claims.

### REFERENCE SYMBOLS

1 evaluation electronics
2 measuring sensor
3 conductor path
4 connection pad
5 housing
10 connection cable
11 circuit board
12, 12₁, 12₂, 12₃, 12₄ bending section
13₁, 13₂, 13₃, 13₄, 13₅ circuit board section
14₁, 14₂, 14₃, 14₄ bridge
15₁, 15₂ circuit board end sections
16 bridges
17 bridges
18 marginal section of the carrier 20
19 marginal section of the carrier 20
20 carrier, PCB panel
21₁, 21₂, 21₃ spiral transition
22 bridges
23 bridges
100 measuring module
S slit

What is claimed is:

1. A connection cable, for an electric connection of a measuring sensor and an evaluation electronics circuit of a fill level measuring module, wherein said connection cable comprises:
(a) a flexible circuit board, said flexible circuit board further comprising:
(i) at least one conductor path;
(ii) at least two circuit board sections lying next to each other and connected via at least one bending section; and
(iii) adjacent areas of said flexible circuit board being detachably connected via a bridge;
(b) a first and a second circuit board end section;
(c) a plurality of circuit board sections, wherein each one of said plurality of circuit board sections is of essentially the same length located in between, and wherein said first and said second circuit board end sections are designed as connection points projecting above a plurality of bending sections, said plurality of bending sections lying opposite in the direction of said plurality of circuit board sections, with its extension transversely to the direction of said plurality of circuit board sections essentially corresponding to the width of said plurality of circuit board sections lying next to each other; and
(i) wherein said first circuit board end section, as a connection point, is connected with said measuring sensor and said second circuit board end section, as a connection point, with said evaluation electronics circuit; and
(ii) wherein said first and said second circuit board end sections are detachably connected with the said plurality of adjacent bending sections, in each case, by at least one bridge, thereby facilitating an extension of said connection cable to adapt its length to the distance between said measuring sensor and said evaluation electronics circuit.

2. The connection cable, according to claim 1, wherein: each one of said plurality of circuit board sections is designed in a straight line and lying parallel next to each other.

3. The connection cable, according to claim 1, wherein: each of said circuit board end sections is designed essentially rectangular as connection points.

4. The connection cable, according to claim 1, wherein: a circuit board with at least 2n+1 (n≧3) circuit board sections, said first and said second circuit board end sections are connected in each case with all of said plurality of adjacent bending sections via corresponding detachable bridges.

5. The connection cable, according to claim 1, wherein: a plurality of said flexible circuit boards is arranged parallel in a carrier relative to the said plurality of circuit board sections, and adjacent flexible circuit boards are detachably connected, in each case, in the area of said first and said second circuit board end sections via corresponding detachable bridges.

6. The connection cable, according to claim 5, wherein: one of said first and respectively said second circuit board end sections of said flexible circuit boards, is each case connected with each other via said detachable bridge, and in each case together form a marginal section of said carrier.

7. The connection cable, according to claim 6, wherein: said bridges are arranged, in each case, on a side of an edge of said marginal section.

8. The connection cable, according to claim 6, wherein: said two marginal sections form opposite sides of said carrier having an essentially rectangular shape.

9. A connection cable, for an electric connection of a measuring sensor and an evaluation electronics circuit of a fill level measuring module, with said connection cable being designed as a flexible circuit board with at least one conductor path:
(a) wherein said flexible circuit board, starting with a first circuit board end section, is designed helically in one plane with a plurality of spiral turns running outwardly and ending in a second circuit board end section,
(b) wherein said first circuit board section, as a connection point, is connected with said measuring sensor and said second circuit board section as a connection point with said evaluation electronics circuit; and
(c) wherein, in each case, a bridge is provided between each one of said plurality of spiral turns that detachably connect adjacent spiral turns of said flexible circuit board, thereby facilitating an extension of said connection cable to adapt its length to the distance between said measuring sensor and said evaluation electronics circuit.

10. The connection cable, according to claim 9, wherein: a bridge is provided after each half spiral turn.

11. The connection cable, according to claim 10, wherein: at least one bridge is provided in the area of said second circuit board end section.

12. A connection cable system, for an electric connection of a measuring sensor and an evaluation electronics circuit of a measuring module, in particular of a module for fill level measuring technology, with said connection cable being designed as a flexible circuit board with at least one conductor path, comprising:
(a) two flexible circuit board sections, starting with a bending section connecting said two circuit board sections, are designed as coils bifilarly vertically to the plane of said flexible circuit board, running spirally outwardly with a plurality of spiral turns, and ending with a corresponding circuit board end section;
(b) a first circuit board end section as a connection point is connected with said measuring sensor and a second circuit board end section as a connection point with said evaluation electronics circuit; and
(c) an extension of said connection cable is facilitated to adapt its length to the distance between said measuring sensor and said evaluation electronics circuit by uncoiling said extension cable.

13. The connection cable system, according to claim 12, wherein: a differential of a half spiral turn is provided between each of said circuit board end sections.

14. The connection cable system, according claim 13, wherein: a plurality of flexible circuit boards are arranged in a carrier and a set of adjacent circuit boards in the area of a plurality of said spiral turns and/or in the area of said circuit board end sections are detachably connected via a set of corresponding bridges.

15. The connection cable system, according to claim 14, wherein: said carrier is a PCB panel.

16. The connection cable system, according to claim 12, wherein: said circuit board end sections are designed as connection points having an essentially rectangular shape.

17. The connection cable system, of claim 14, wherein:
said measuring module further comprises:
(a) a housing to accommodate a measuring sensor and an evaluation electronics circuit; wherein:
(ii) said measuring sensor and said evaluation electronics circuit are connected via said connection cable; and
(ii) said first circuit board section, as a connection point, is connected with said measuring sensor and said second circuit board section as a connection point with said evaluation electronics circuit.

18. The connection cable system, according to claim 17, wherein
said measuring module is operably arranged, either by breaking each of said corresponding bridges of said connection cable and unfolding said broken bridge or by uncoiling said connection cable,
wherein an extension of said connection cable is facilitated in order to adapt the length of said connection cable to the distance between said measuring sensor and said evaluation electronics circuit that are arranged in said housing.

19. The connection cable system, according to claim 17, wherein: said housing of said measuring module is operably designed as a cylinder, with said measuring sensor and said evaluation electronics circuit being arranged on opposite end walls of said cylinder-shaped housing.

20. The connection cable system, according to claim 17, wherein: said connection cable in its unfolded or uncoiled state has a length at which said measuring sensor and said evaluation electronics circuit are connectable prior to their installation in said cylinder-shaped housing by means of said connection cable that is run through said housing.
